(19) United States
(12) Patent Application Publication
(10) Pub. No.: US 2026/0280569 A1
(43) Pub. Date: Sep. 17, 2026

(54) PHASE LOCKED LOOP CIRCUIT WITH TIME INTERLEAVED PHASE FREQUENCY DETECTORS

(71) Applicant: Telefonaktiebolaget LM Ericsson (publ), Stockholm (SE)

(72) Inventors: Henrik SJÖLAND, Lund (SE); Mohammed ABDULAZIZ, Lund (SE); Tony PÅHLSSON, Lund (SE)

(21) Appl. No.: 19/168,674

(22) PCT Filed: Mar. 28, 2023
(86) PCT No.: PCT/EP2023/058071

§ 371 Date: Sep. 24, 2025

(51) Int. Cl. H03L 7/087; H03L 7/099; H03L 7/18; H04L 7/027

(52) U.S. Cl. CPC H03L 7/087; H03L 7/099; H03L 7/18; H04L 7/027

(57) ABSTRACT

A Phase Locked Loop includes a digitally controlled oscillator (DCO), an integer number M of Phase Frequency Detectors (PFDs), M Time to Digital Converters (TDCs) connected to the outputs of the M PDFs respectively, a first frequency divider configured to generate M frequency-divided reference signals shifted in time by one period Tr of the reference signal from each other; a second frequency divider configured to generate M frequency-divided feedback signals shifted in time by one period Tf of the feedback signal from each other; a third frequency divider configured to generate a feedback signal to the second frequency divider; a digital processing unit configured to generate an output signal per cycle of the reference signal based on received signals from the M TDCs; and a loop filter configured to generate a control signal to the DCO to adjust the frequency of the output signal generated from the DCO.

### TECHNICAL FIELD

Embodiments herein relate to Phase Locked Loop (PLL) circuits. In particular, they relate to digital PLL circuits, transceivers and electronic devices comprising the digital PLL circuits.

### BACKGROUND

There is a need for accurate local oscillator (LO) signals in wireless transceivers. This is also the case for multi-antenna transceivers that will be used in the 5^{th} and 6^{th} generation (5G/6G) communication systems. Multiple transceivers are usually integrated on a chip. There will be challenges to supply the multiple transceivers at different locations on the same chip with high spectral purity phase coherent LO signals. Operating frequencies of the multiple transceivers are also foreseen to increase, making it increasingly difficult to achieve sufficiently low phase noise on LO signals.

Typically, LO signals are generated using phase locked loops (PLLs). Traditionally analog PLLs have been used, but lately also digital ones. Currently both options are viable, with different pros and cons. A digital PLL has advantages in the absence of an analog loop filter with large area capacitors, and possibility to support advanced digital algorithms to, for instance, speed up frequency hops. An analog PLL on the other hand is much less complex to design and may have excellent performance regarding phase noise. For instance, at very high frequencies or for very low power, the simplicity of an analog PLL makes it an excellent choice. Choosing an analog PLL, however, the possibilities of using digital algorithms to achieve improved performance may be sacrificed. Regardless of using an analog or digital PLL, a key concern is how to achieve sufficiently low phase noise with limited power consumption and chip area, without sacrificing any other aspect.

An attractive option for a digital PLL is to use a phase frequency detector (PFD) followed by pulse shrinking time to digital converters (TDCs) measuring a pulse length as disclosed in WO 2022/128049 A1. The robust frequency detection of analog PLLs enabling fast and simple acquisition of lock is then combined with digital signal processing opportunities, at a very low TDC power consumption.

To obtain a sufficiently low phase noise at very high carrier frequencies of future millimetre (mm) wave systems, like 6G, will be a major challenge in PLL design. To reduce the phase noise the PLLs will have to operate with much higher reference frequencies than today. Operating at significantly higher speed calls for new solutions in phase detection.

While the PFD has several advantages, like providing not only phase but also frequency detection, and outputting short pulses near zero phase error, i.e. at lock, it has speed limitations. The flip flops in the PFD must be reset between each operation, which takes some time. Although the reset time is short, for efficient operation it must only be a small fraction of the reference signal period. If the reference frequency is 10 GHz, its period is just 100 ps, and the limited speed of the PFD will then impact the performance.

Also, the TDCs have a limit in maximum sample rate, for similar reasons as the PFD, as they need to be read out and depending on architecture they may also have to be reset. For a high-resolution pulse shrinking line or delay line in a conventional TDC, time is also required for the signal pulse to propagate through multiple stages.

Both the PFD and TDC have limits in maximum clock frequency and approaching those limits result in reduced performance. Using existing solutions based on PFDs and/or TDCs, it will thus not be possible to use the increased reference frequencies necessary to achieve sufficiently low phase noise at realistic power consumption for future 6G high mm wave frequency communications.

### SUMMARY

Therefor it is an object of embodiments herein to provide a Phase Locked Loop (PLL) circuit with improved performance.

According to a first aspect of embodiments herein, the object is achieved by a PLL circuit. The PLL circuit comprises a digitally controlled oscillator (DCO) configured to generate an output signal.

The PLL circuit further comprises an integer number M of Phase Frequency Detectors (PFDs). Each PFD has a first input (RefD), a second input (FBD) and a first output (CU) and a second output (CD).

The PLL circuit further comprises M Time to Digital Converters (TDCs) connected to the outputs of the M PDFs respectively.

The PLL circuit further comprises a first frequency divider configured to receive a reference signal and frequency divide the reference signal by M to generate M frequency-divided reference signals shifted in time by one period Tr of the reference signal from each other. The M frequency-divided reference signals are input to the first inputs of the M PFDs respectively.

The PLL circuit further comprises a second frequency divider configured to receive a feedback signal and frequency divide the feedback signal by M to generate M frequency-divided feedback signals shifted in time by one period Tf of the feedback signal from each other. The M frequency-divided feedback signals are input to the second inputs of the M PFDs respectively.

The PLL circuit further comprises a third frequency divider configured to receive the output signal from the DCO and frequency divide the output signal from the DCO to generate the feedback signal to the second frequency divider.

The PLL circuit further comprises a digital processing unit configured to receive signals from the M TDCs and generate an output signal (OutD) per cycle of the reference signal based on the received signals from the M TDCs.

The PLL circuit further comprises a loop filter configured to receive the output signal from the digital processing unit and generate a control signal to the DCO to adjust the frequency of the output signal generated from the DCO.

According to some embodiments herein, the digital processing unit is configured to generate an output signal per cycle of the reference signal based on the received signals from the M TDCs by multiplexing the outputs of the M TDCs so that the outputs from the M TDCs are combined to one output signal with a data updating frequency M times the data updating frequency of a single TDC among the M TDCs.

In other words, the embodiments herein provide a PLL circuit comprising M PFDs followed by M TDCs. The M PFDs are time interleaved. To accomplish this, digital frequency divider circuits, i.e. the first and second frequency divider, are used to divide the reference signal and the PLL feedback signal by M. The frequency dividers reduce the frequency by a factor M and produce M equidistantly time interleaved or skewed clock phases. The M frequency-divided reference signals and M frequency-divided feedback signals with equidistantly time skewed clock phases are two input clock signals to the M PFDs. The output signals of each PFD are fed to TDC e.g. a pulse shrinking TDC. Effectively, at each reference clock cycle, one TDC can be read out, providing the same information as if there were no time interleaving, and hence utilizing the high reference frequency as intended. Each TDC and PFD, however, have M times longer to perform their operation.

When there is a single PFD in the PLL circuit, there is no problem related to synchronization. However, using several PFDs time interleaved, if the PFDs have different states, the PLL circuit will not lock with zero-degree phase error, which will cause problems in phased array systems with multiple PLLs, as unpredictable phase relations would then occur. Moreover, mismatches in the frequency dividers, PFDs and TDCs will cause interleaving spurs resulting a fixed error pattern of length M to the output signal of the interleaved PFDs during the PLL locked state. Methods to synchronize the M PFDs and mitigate interleaving spurs are also provided.

According to some embodiments herein, to synchronize the M PFDs, one of the M PFDs may be set as a master PFD and the TDC connected to the master PFD is configured to detect whether a significant pulse with a polarity of either positive or negative is generated at the output of the master PFD. A pulse being significant means a duration length of the pulse is larger than a threshold. If a significant pulse is detected, the TDC generates a force signal to other PFDs to enforce the other PFDs to generate output pulses with the same polarity as that of the master PFD.

In other words, to synchronize the M PFDs, an example embodiment is setting one PFD as a master and other PFDs as slaves. If the TDC of the master PFD detects a significant pulse in either polarity or direction, i.e. positive or negative, at the output of the master PFD, the other PFDs with output pulses in the other direction are reset until each slave PFD detects an input pulse that creates an output with the polarity of the master. This is realized by generate a first and second force signals, i.e. a charge-up and a charge-down force signals from the TDC connected to the master PFD for resetting the slave PFDs.

According to some embodiments herein, to synchronize the M PFDs, the digital processing unit may be configured to calculate an averaged value for each TDC by averaging the output values of each TDC over a number of the frequency-divided reference signal cycles and calculate a compensation value by averaging the M averaged values of the M TDCs. The digital processing unit is further configured to determine if the PLL is locked or not. If the PLL is locked, the digital processing unit is further configured to calculate a deviation value for each TDC by subtracting the compensation value from the averaged value of each TDC and detect the largest magnitude of the deviation values of the M PFDs. If the largest magnitude exceeds a threshold, and if the deviation value with the largest magnitude is positive, the digital processing unit is further configured to subtract an adjustment value from the value of the output signal of the digital processing unit for a number of the frequency-divided reference signal cycles. If the deviation value with the largest magnitude is negative, the digital processing unit is further configured to add an adjustment value to the value of the output signal of the digital processing unit for a number of the frequency-divided reference signal cycles.

According to some embodiments herein, to mitigate interleaving spurs, the digital processing unit may be configured to calculate an averaged value for each TDC by averaging the output values of each TDC over a number of the frequency-divided reference signal cycles; calculate a compensation value by averaging the averaged values of the M TDCs; calculate a deviation value for each TDC by subtracting the compensation value from the averaged value of each TDC; and subtract the M deviation values of TDCs from the respective outputs of the M TDCs.

In other words, when it comes to mitigation interleaving spurs, the fixed error pattern is identified and subtracted from the TDC outputs. To detect the fixed error pattern, each of the M TDC outputs are first averaged individually over a period of time, and then these averaged values form the M TDCs are averaged to get an overall compensation value. For each TDC, a deviation value is calculated between its averaged value and the compensation value. These M deviation values are the fixed error pattern. Before using a value in a TDC, the deviation value is subtracted from its value. The averages can be calculated continuously to track pattern changes due to e.g. temperature variations.

According to a second aspect of embodiments herein, the object is achieved by a method performed in a PLL for generating an output signal.

The method comprises generating M frequency-divided reference signals by a first frequency divider configured to receive a reference signal and frequency divide the reference signal by M. The M frequency-divided reference signals are shifted in time by one period Tr of the reference signal from each other.

The method further comprises receiving the M frequency-divided reference signals at first inputs of M Phase Frequency Detectors (PFDs) respectively.

The method further comprises generating M frequency-divided feedback signals by a second frequency divider configured to receive a feedback signal and frequency divide the feedback signal by M. The M frequency-divided feedback signals are shifted in time by one period Tf of the feedback signal from each other.

The method further comprises receiving the M frequency-divided feedback signals at second inputs of the M PFDs respectively.

The method further comprises generating the feedback signal to the second frequency divider by a third frequency divider configured to receive an output signal from a digitally controlled oscillator (DCO) and frequency divide the output signal from the DCO.

The method further comprises receiving signals from the M TDCs by a digital processing unit.

The method further comprises generating an output signal per cycle of the reference signal by the digital processing unit based on the received signals from the M TDCs.

The method further comprises receiving the output signal from the digital processing unit by a loop filter.

The method further comprises generating a control signal by the loop filter to the DCO.

The method further comprises receiving the control signal and generating an output signal by the DCO (110). The frequency of the output signal generated from the DCO is adjusted by the control signal.

The PLL circuit and method according to embodiment herein have some advantages, for examples:

The M PFDs and TDCs in the PLL circuit operate in a time interleaved fashion with the M frequency-divided reference signals and M frequency-divided feedback signals. A reference signal with higher frequency can then be used, enabling very low phase noise in high mm wave PLLs for 5G and 6G communications.

The PLL circuit has M times increased detection range in each PFD and M times larger maximum signal resulting faster locking of the PLL circuit.

The PLL locks with close to zero phase error and with short PFD pulses thanks to the solution of synchronization between the interleaved M PFDs. Phase errors between different PLLs in an antenna array system can be avoided, and power consumption is also reduced in TDCs by securing short pulses in locked state.

Simple mitigation technique for interleaving spurs is provided for the PLL circuit, which can continuously track and suppress interleaving spurs. The mitigation technique is much simpler than in analog to digital convertors (ADCs), as the signals in locked PLL state are both small and almost static.

The PLL circuit is scalable to a different number M of PFDs.

The PLL circuit is robust on acquisition of lock by using PFD.

All components in the PLL circuit are digital eliminating large analog loop filter.

Therefore, the embodiments herein provide an improved PLL circuit with regard to phase noise, power consumption, size, and robustness etc.

### BRIEF DESCRIPTION OF THE DRAWINGS

Examples of embodiments herein are described in more detail with reference to attached drawings in which:

FIG. 1 is a schematic block view of a PLL circuit according to embodiments herein;

FIG. 2 is a diagram showing simulation results for an example PLL circuit with 4 parallel interleaved PFDs according to embodiments herein;

FIG. 3 is a block diagram illustrating an example PFD according to embodiments herein;

FIG. 4 is a block diagram illustrating another example PFD according to embodiments herein;

FIG. 5 is a block diagram illustrating another example PFD according to embodiments herein;

FIGS. 6a and 6b are flow charts of methods according to embodiments herein;

FIG. 7 is a block diagram illustrating function units of a digital processing unit according to embodiments herein; and

FIG. 8 is a block diagram illustrating an electronic device in which a PLL circuit according to embodiments herein may be implemented.

### DETAILED DESCRIPTION

Embodiments herein provide a PLL circuit comprising M PFDs followed by M TDCs. The M PFDs are time interleaved. To accomplish this, digital frequency divider circuits are used to divide the reference signal and feedback signal by M. The frequency dividers reduce the frequency by a factor M and produce M equidistantly time interleaved or skewed clock phases. The M frequency-divided reference signals and M frequency-divided feedback signals with equidistantly time skewed clock phases are two input clock signals of the M PFDs. The output signals of each PFD are fed to TDC. Effectively, at each reference clock cycle, one TDC output can be read out, providing the same information as if there were no time interleaving, and hence utilizing the high reference frequency as intended. Each TDC and PFD, however, have M times longer to perform their operation.

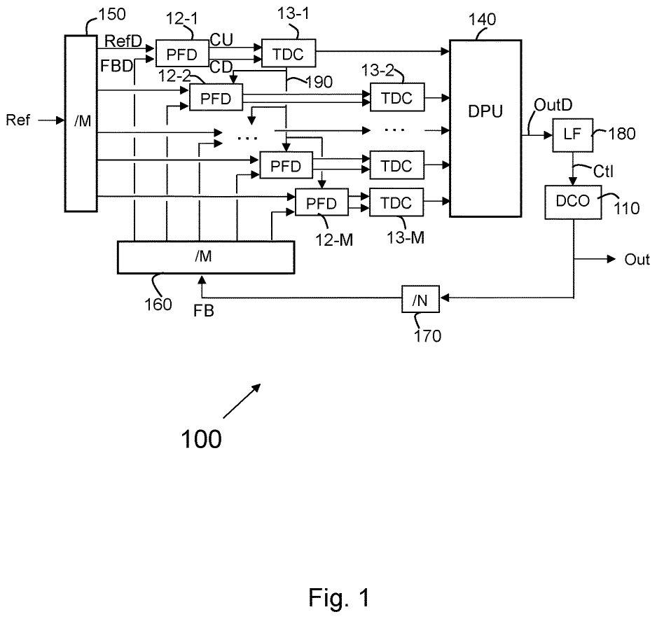

FIG. 1 shows a PLL circuit 100 according to embodiments herein. As can be seen from FIG. 1, the PLL circuit 100 comprises a digitally controlled oscillator DCO 110 configured to generate an output signal Out.

The PLL circuit 100 further comprises an integer number M of Phase Frequency Detectors PFDs 12-1, 12-2, . . . 12-M. Each PFD having a first input RefD, a second input FBD and a first output, i.e. charge-up CU and a second output, i.e. charge-down CD.

The PLL circuit 100 further comprises M Time to Digital Converters TDCs 13-1, 13-2, . . . 13-M, connected to the outputs of the M PDFs respectively.

The PLL circuit 100 further comprises a first frequency divider 150 configured to receive a reference signal Ref and frequency divide the reference signal by M to generate M frequency-divided reference signals shifted in time by one period Tr of the reference signal from each other. The M frequency-divided reference signals are input to the first inputs RefD of the M PFDs respectively.

The PLL circuit 100 further comprises a second frequency divider 160 configured to receive a feedback signal FB and frequency divide the feedback signal by M to generate M frequency-divided feedback signals shifted in time by one period Tf of the feedback signal from each other. The M frequency-divided feedback signals are input to the second inputs FBD of the M PFDs respectively.

The PLL circuit 100 further comprises a third frequency divider 170 configured to receive the output signal Out from the DCO 110 and frequency divide the output signal from the DCO 110 to generate the feedback signal FB to the second frequency divider 160.

The PLL circuit 100 further comprises a digital processing unit DPU 140 configured to receive signals from the M TDCs 13-1, 13-2, . . . 13-M and generate an output signal OutD per cycle of the reference signal Ref based on the received signals from the M TDCs 13-1, 13-2, . . . 13-M.

The PLL circuit 100 further comprises a loop filter LF 180 configured to receive the output signal OutD from the digital processing unit 140 and generate a control signal Ctl to the DCO 110 to adjust the frequency of the output signal Out generated from the DCO 110. As can be seen both the reference signal Ref and feedback signal FB are input to a digital frequency divider that divides the frequency by M and creates M output signals. When the input signal to a frequency divider has a stable frequency, the signals at the outputs of the frequency divider are equal but separated in time by one input signal period. The reference signal Ref is stable in frequency and has a period of Tr. As an example, the PFD 12-1 at the top may receive its signal one reference signal period before the one below, i.e. PFD 12-2, which in turn receives its signal one reference signal period before the one below it, and so on. Each frequency divider by M splits up the transitions of the high frequency input signal on the M output signals, so that each PFD receives every M: th signal transition. Every reference signal cycle, one PFD thus receives a reference signal edge, so that all reference signal edges are processed by the M PFDs and none are missed. Each PFD receives a reference signal edge every M: th reference signal cycle. Every reference signal edge is thus compared to an edge of the feedback signal.

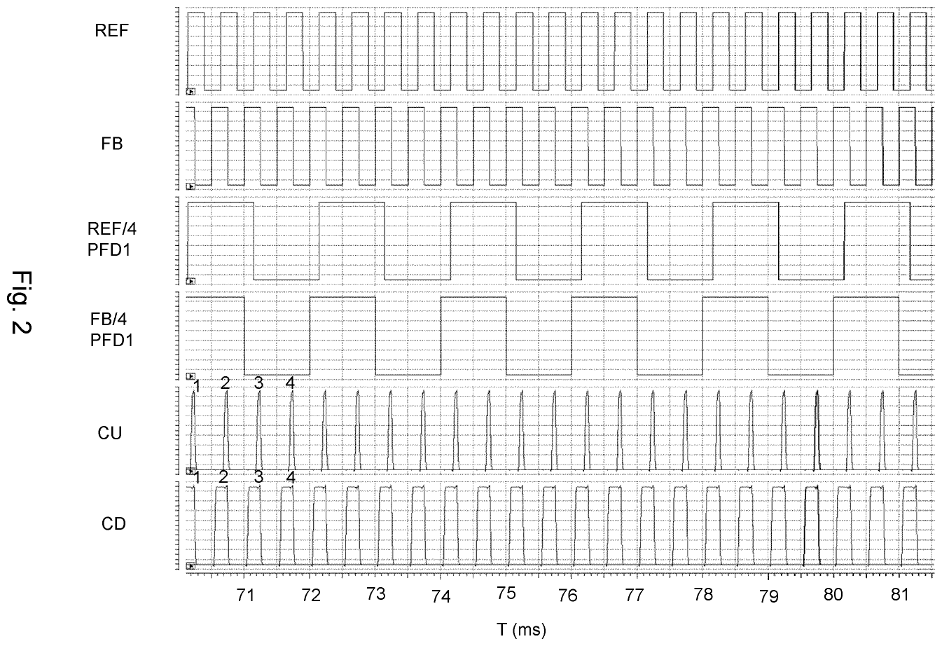

FIG. 2 shows a simulation example of four parallel time interleaved PFDs, i.e. M=4. Both the reference signal REF and the feedback signal FB are frequency divided by four generating 4 frequency-divided signals shifted in time by one period Tr of the reference signal, or in this case by 90° from each other. The reference signal, the feedback signal, the frequency-divided reference signal and the frequency-divided feedback signal to the first PFD are shown in FIG. 2 indicated by REF, FB, REF/4 PFD1, FB/4 PFD1, respectively. The output pulses, i.e. the charge-up and charge-down pulses, from the four PFDs are also shown in FIG. 2 indicated by CU 1,2,3,4 and CD 1,2,3,4. As can be seen, the four charge-up pulses CU 1,2,3,4 are time interleaved by one reference signal period Tr, and the four charge-down pulses CD 1,2,3,4 are also time interleaved by one reference signal period Tr. The four PFDs generate four time interleaved output pulses that, if they were added or combined together, are similar to if one single PFD had generated them with the reference signal frequency REF and feedback signal frequency FB as inputs without division.

The PFDs generate charge-up and charge-down pulses in response to the timing of the input pulses. The length of the charge-up and charge-down pulses are digitized by a TDC, for instance a pulse length modifying TDC. Examples of a pulse length modifying TDC include pulse shrinking TDC and pulse extending TDC.

Generally, a pulse length modifying TDC is configured to provide a digital representation of the pulse length of a signal input to it, i.e. a received signal, by successively modifying the pulse length of the received signal and detect when the pulse length has reached a threshold value.

For example, a pulse shrinking TDC is configured to provide a digital representation of the pulse length of the received signal by successively shrinking the pulse length of the received signal and detect when the pulse length has reached zero i.e., when the pulse has vanished.

For example, a pulse extending TDC is configured to provide a digital representation of the pulse length of the received signal by successively extending the pulse length of the received signal and detect when the pulse length has reached maximum pulse length i.e., when the pulse is fully extended in the time range under consideration.

Alternatively or additionally, a pulse extending TDC may be described as configured to provide a digital representation of the pulse length of the received signal by successively shrinking the length of a negative pulse and detect when that length has reached zero i.e., when the negative pulse has vanished. Thus, pulse shrinking and pulse extending may be seen as the same operation, i.e., shrinking applied to a (positive) pulse in the first case and shrinking applied to a negative pulse in the second case.

Phase frequency detectors and pulse extending TDCs are conceptually well known and their general functionality and known implementation variants will not be elaborated on in length herein. Pulse shrinking TDCs will be used as non-limiting exemplification herein.

Not shown in FIG. 1 is the clocking of the TDCs which uses the output signal phases of the reference signal divider 150. The digitized charge-up pulse length is then subtracted by the digitized charge-down pulse length in the TDC, and the result is fed to a digital multiplex and spur suppression block, i.e. the DPU 140. Also this block uses the multiple signal phases from the reference signal divider 150 for clocking different functional units in this block and reading the TDC outputs at proper times.

Generally, each PFD has an internal state due to the memory in flip-flop circuits comprised in the PFD, which is why it can detect frequency. When there is a single PFD in the PLL circuit, there is no problem related to synchronization. However, using several PFDs time interleaved, if the PFDs have different states the PLL circuit will not lock with zero degree phase error, which will cause problems in phased array systems with multiple PLLs, as unpredictable phase relations would then occur. Moreover, mismatches in the frequency dividers, PFDs and TDCs will cause interleaving spurs resulting a fixed error pattern of length M to the output signal of the interleaved PFDs during the PLL locked state. Methods to synchronize the M PFDs and mitigate interleaving spurs are provided herein.

To mitigation interleaving spurs, the fixed error pattern is identified and subtracted from the TDC outputs. To detect the fixed error pattern, each of the M TDC outputs are first averaged individually over a period of time, and then these averaged values form the M TDCs are averaged to get an overall compensation value. For each TDC, a deviation value is calculated between its averaged value and the compensation value. These M deviation values are the fixed error pattern. These averaged values for all PFDs can be calculated continuously to track the error pattern changes due to e.g. temperature variations.

Therefore, according to some embodiments herein, the digital processing unit DPU 140 may be further configured to calculate an averaged value for each TDC by averaging the output values of each TDC over a number of the frequency-divided reference signal cycles or over a period of time.

Different averaging algorithms can be used, for instance a method with a forgetting factor may be beneficial for its simplicity requiring very little memory. The old averaged value is then multiplied with a factor slightly less than unity, to slowly forget, and then the latest output value is multiplied by one minus the factor and added to that, which is then stored as the new averaged value. An alternative may be to keep old averaged values in memory for some time, and weight them together to get the averaged value. Regardless, it is important to only use output values from the TDCs when the PLL is in locked state in the calculation, as the output values from the TDCs during lock acquisition are not relevant as well as being large and causing significant deviations.

As described above these averaged values for the M TDCs are then averaged to find a compensation value, from which deviation values are to be calculated. Then these deviation values are subtracted from the respective output values of the M TDCs, before these values are multiplexed to yield an output data per reference signal cycle. Thus, both the reference signal clock and the M frequency-divided reference signal clocks are used in the DPU 140 for selecting and outputting the TDC outputs at proper times.

Therefore, according to some embodiments herein, the digital processing unit DPU 140 may be further configured to calculate a compensation value by averaging the averaged values of the M TDCs; calculate a deviation value for each TDC by subtracting the compensation value from the averaged value of each TDC and subtract the M deviation values of TDCs from the respective outputs of the M TDCs.

According to some embodiments herein, the digital processing unit DPU 140 is configured to generate an output signal OutD per cycle of the reference signal Ref based on the received signals from the M TDCs 13-1, 13-2, . . . 13-M by multiplexing the outputs of the M TDCs so that the outputs from the M TDCs are combined to one output signal with a data updating frequency M times the data updating frequency of a single TDC among the M TDCs. The multiplexing function or a multiplexer is a data selector which takes several inputs and gives a single output. That means the digital processing unit DPU 140 selects an output from one of the M TDCs at every cycle of the reference signal.

This output signal OutD from the DPU 140 is then fed to the loop filter LF 180, clocked by the reference signal. The loop filter LF 180 shapes the loop gain of the PLL circuit 100 and creates the control signal Ctl to the digitally controlled oscillator DCO 110, that generates the PLL output signal Out. The output signal Out is frequency divided by N in a feedback divider i.e. the third frequency divider 170, whose output signal is connected to divide by M circuit of the feedback signal, i.e. the second frequency divider 160.

According to some embodiments herein, the digital processing unit 140 may be further configured to continuously calculate an averaged value for each TDC over a period of time to track the error pattern changes due to e.g. temperature variations.

To synchronize the M PFDs, an example embodiment may be to set one PFD as a master and other PFDs as slaves. If the TDC of the master PFD detects a significant pulse in either polarity or direction, i.e. positive or negative, at the output of the master PFD. A pulse being significant means a duration or length of the pulse is larger than a threshold. The other PFDs with output pulses in the other direction are reset until each slave PFD detects an input pulse that creates an output with the polarity of the master. This is realized by generate a first and second force signals, i.e. charge-up and a charge-down force signals from the TDC connected to the master PFD for resetting the slave PFDs.

Therefore, according to some embodiments herein, one of the M PFDs is set as a master PFD, e.g. the PFD 12-1, and the TDC 13-1 connected to the master PFD 12-1 may be configured to detect whether a significant pulse with a polarity of either positive or negative is generated at the output of the master PFD, and if a significant pulse is detected, generate a force signal 190 to other PFDs to enforce the other PFDs to generate output pulses with the same polarity as that of the master PFD 121.

As shown in FIG. 1, there are signals 190 from one of the TDCs connected to the other PFDs. In this case the top most PFD 12-1 is the master. The TDC 13-1 connected to the master PFD 12-1 will detect if there is a significant pulse at the charge-up CU or charge-down CU output signal. The TDC 13-1 will output a signal indicating either no significant pulse, charge-up pulse significant, or charge-down pulse significant. This may be represented by two wires carrying binary signals, where a binary signal being asserted corresponds to a significant pulse of corresponding polarity, i.e. charge-up or charge-down, being present at the latest output of the master PFD 12-1. When a significant pulse is present, for the other PFDs to be in the same state they should output a pulse of the same type, i.e. charge-up or charge-down, despite some mismatch.

The threshold for determining if there is a significant pulse at the output of the master PFD 12-1, hereafter referred to as a significant pulse length threshold Tₛ, determines if the slave PFDs should be forced to a corresponding polarity as the master PFD 12-1, i.e. if a force signal 190 to other PFDs should be generated. If a pulse length in the master PFD is longer or larger than the significant pulse length threshold Tₛ, the corresponding force signal is generated.

The significant pulse length threshold Tₛ must hence be made longer than the maximum mismatch Tₘ between all signal branches or channels, including mismatch in the divide by M circuits, the PFDs, and the TDCs. The phase relation between the reference and the feedback signals can also be different between the PFDs when the feedback frequency deviates from the reference frequency. Large frequency deviations may occur during initial acquisition of the PLL, but then all PFDs will detect the frequency error and generate pulses with the same polarity anyway, so there will be no decisions forcing PFDs to the wrong state, so the significant pulse length threshold does not need any additional margin due to input signal phase differences between the PFDs. During locked operation of the PLL, the phase fluctuations will be due to phase noise, mainly due to frequencies above the reference frequency divided by M, which will be small in high performance PLLs. However, the worst case of this integrated phase noise, i.e. jitter Tⱼ representing phase noise in time domain, should be added to the significant pulse length threshold Tₛ to avoid decisions forcing PFDs to change state at the wrong time. On the other hand, the significant pulse length threshold Tₛ should not be so long that the case of a single PFD operating in a different state during PLL lock can go undetected. That situation ideally corresponds to a pulse length equal to one reference period Tr, to which mismatch Tₘ should be subtracted, but jitter does not need to be corrected for, as a wrong decision just means a missed synchronization opportunity, which is no problem as new ones will come again and again, and then the system will synchronize. The equation below describes the above considerations for selection of the significant pulse length threshold Tₛ:

$${T}_{m} + {T}_{j} + {T}_{mg} < {T}_{s} < Tr - {T}_{m} \qquad ( 1 )$$

Where T_{mg} is a margin added to the mismatch Tₘ and jitter Ti to ensure a safe operation where the M PFDs are in the same state and are only excited by jitter and mismatch. The margin T_{mg} may be determined as required according to different application scenarios. For example, a margin of three standard deviation values of the mismatch Tₘ and jitter Tⱼ may be added to make sure that errors beyond that indicate a synchronization issue.

For instance, if the reference frequency is 10 GHz, so the period Tr is 100 ps, the maximum mismatch Tₘ may be 2 ps, the jitter Tⱼ above 1.25 GHz may be 20 ps, and the margin T_{mg} may be 20 ps. The significant pulse length threshold Tₛ may then be chosen between 42 ps and 80 ps. In case the jitter is large and it is difficult to fulfil the above equation, the upper limit can be increased, relying on jitter to provide extension of some pulses so that they are detected and synchronization will occur also in this pessimistic case, assuming the PLL to reach locked state with one PFD out of phase is pessimistic, as it would likely be detected before reaching stable state, and synchronized. As a rule of thumb, the significant pulse length threshold Tₛ may be selected close to the reference period Tr for robust operation.

Therefore, according to some embodiments herein, the significant pulse length threshold may be determined based on jitter and mismatches between the M PFDs, between the M TDCs and in the first and second frequency dividers, and the period of the reference signal.

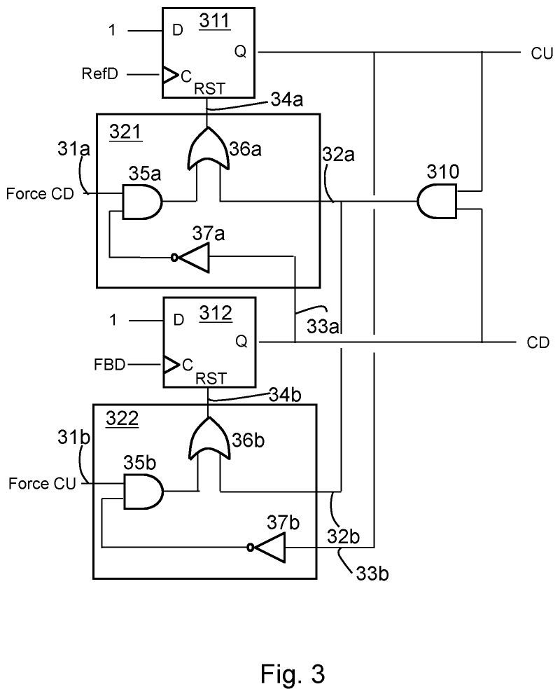

When a significant pulse of the master PFD is detected, the other PFDs should be forced to output the same polarity pulse, to operate in the same state. This may be accomplished by providing two first flip-flop circuits comprised in the PFD with a force signal 190 comprising a first force signal, i.e. force charge-down Force CD, and a second force signal, i.e. force charge-up Force CU. FIG. 3 shows a schematic block diagram of a PFD 300 with synchronization input signals Force CD and Force CU.

The PFD 300 comprises a first and a second flip-flop circuits 311, 312 each comprising a first, a second and a third inputs C, D, RST, and an output Q. The first input C of the first flip-flop circuit 311 is the first input RefD of the PFD to receive one of the M divided reference signals, the first input C of the second flip-flop circuit 312 is the second input FBD of the PFD to receive one of the M divided feedback signals.

The PFD 300 further comprises a first and a second logic gates 321, 322, each having a first, a second and a third inputs 31a, 32a, 33a/31b, 32b, 33b and an output 34a/34b. The first and a second logic gates 321, 322 are configured to receive respectively the first and second force signals Force CD, Force CU from the TDC 13-1 connected to the master PFD 13-1 and generate a first and second reset signals to the first and a second flip-flop circuits 311, 312 respectively.

The PFD 300 further comprises an AND gate 310 having two inputs and an output, wherein the outputs CU, CD from the first and second flip-flop circuits 311, 312 are connected to the two inputs of the AND gate 310 respectively, the output of the AND gate 310 is connected to the second inputs 32a/32b of the first and second logic gates 321, 322.

Each logic gate 321, 322 comprises an AND gate 35a/35b, an OR gate 36a/36b and an inverter 37a/37b. In each logic gate 321, 322, a first input of the AND gate 35a/35b is the first input 31a/31b of the logic gate 321/322, an output of the inverter 37a/37b is connected to a second input of the AND gate 35a/35b, an input of the inverter 37a/37b is the third input 33a/33b of the logic gate, an output of the AND gate 35a/35b is connected to a first input of the OR gate 36a/36b, a second input of the OR gate 36a/36b is the second input 32a/32b of the logic gate, and an output of the OR gate 36a/36b is the output 34a/34b of the logic gate.

The output CU from the first flip-flop circuit 311 is connected to the third input 33b of the second logic gate 312; the output CD from the second flip-flop circuit 312 is connected to the third input 33a of the first logic gate 311; the first input 31a of the first logic gate 321 is to receive the first force signal Force CD; the first input 31b of the second logic gate 322 is to receive the second force signal Force CU; the output 34a of the first logic gate 321 is connected to the third input RST of the first flip-flop circuit 311; and the output 34b of the second logic gate 322 is connected to the third input RST of the second flip-flop circuit 312.

As can be seen, the TDC 13-1 connected to the mater PFD 12-1 may generate a reset signal, a force charge-up or a force charge-down signal. The reset signal is not released until the other flip-flop circuit 312 has produced a one at its output. The first flip-flop circuit 311 is then released so it can receive a pulse that will reset the PFD 12-1. This functionality is realized by the first and second logic gates 321, 322 as shown in FIG. 3, and described in the following.

Note that the first and second logic gates 321, 322 shown in FIG. 3 are just examples, other implementations with different gates are possible as long as they fulfil the truth table below:

| Force CD/CU | CD/CU | CD&CU | OUT |
|---|---|---|---|
| (31a/31b) | (33a/33b) | (32a) | (34a) |
| 0 | 0 | 0 | 0 |
| 0 | 0 | 1 | 1 |
| 0 | 1 | 0 | 0 |
| 0 | 1 | 1 | 1 |
| 1 | 0 | 0 | 1 |
| 1 | 0 | 1 | 1 |
| 1 | 1 | 0 | 0 |
| 1 | 1 | 1 | 1 |

The OR gates 36a/36b at the reset inputs of the flip-flop circuits 311/312 allow the synchronization signals to reset the flip-flop circuits. As long as the other flip-flip circuit output a zero, the AND gate 35a/35b will pass the reset signal Force CD/CU, and so will the OR gate 36a/36b. As the other flip-flop circuit outputs a one, the inverter 37a/37b makes one AND gate 35a or 35b input low, and the AND gate 35a or 35b will then output zero, blocking the force signal Force CD/CU. The regular reset path is still enabled, through the OR gate 36a/36b. The OR gate 36a/36b has some delay, but as flip-flop circuits normally are implemented with some delay in the reset path to set a minimum output pulse length, that is of no concern. The delay of the force signal Force CD/CU being disabled after a signal is received by the other flip-flop circuits is, however, important. The flip-flop circuit needs to transition to a high output level, and the inverter, AND gate and OR gates must propagate the signal, and the other flip-flop circuit must get out of the reset state before it can receive a clock signal. This will limit how small pulse width can be tolerated, and this time must be added to the minimum time in Eq. (1), corresponding to increasing the margin T_{mg}, resulting in an upper limit to the reference frequency.

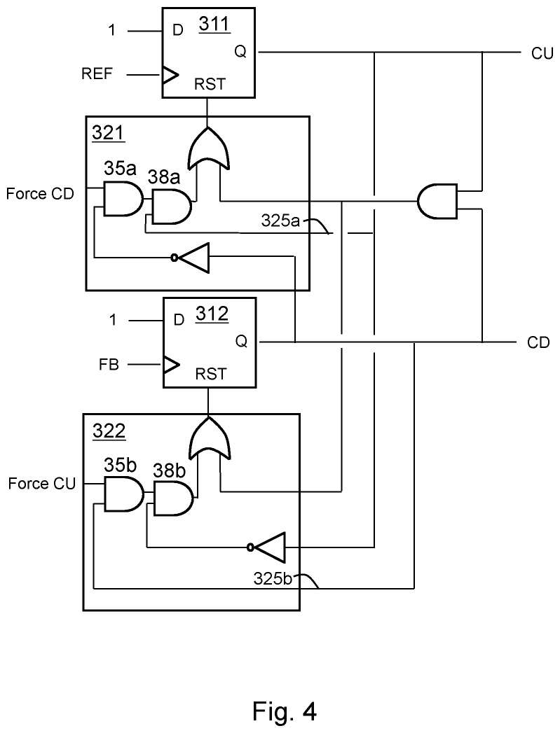

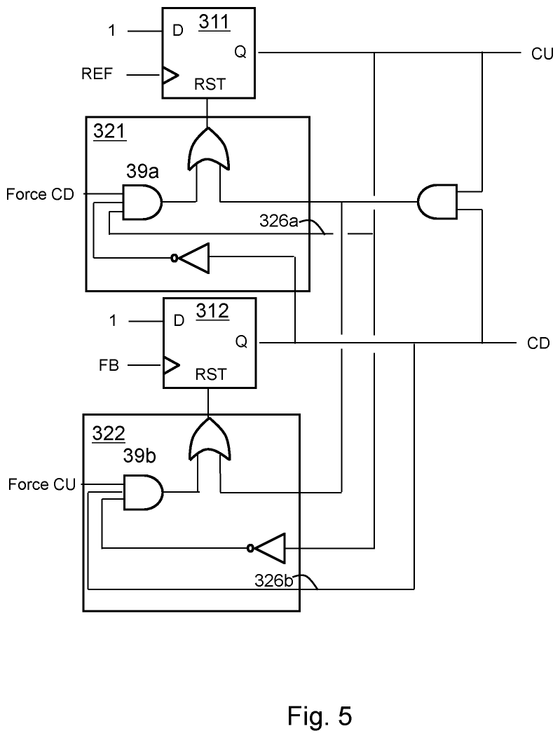

The problem is that the flip-flop circuit may be in reset when its clock signal arrives, and to avoid that the reset pulse can be taken low when the flip-flop circuit output is low. When the flip-flop circuit is already low, reset is not needed, and by not having the flip-flop circuit in reset it will be ready to receive clock pulses. The functionality can be realized by adding another AND gate or using a 3-input AND gate requiring the flip-flop circuit output to be high to pass the synchronization reset signal. FIG. 4 shows one example implementation with an extra AND gate 38a/38b and each of the first and second logic gates 321, 322 further comprises a fourth input 325a/325b. FIG. 5 shows another example implementation with a 3-input AND gate 39a/39b and each of the first and second logic gates 321, 322 further comprises a fourth input 326a/326b. However, with this arrangement there can be a short reset pulse of the wrong polarity at the output of a PFD when its state is changed to synchronize it. The short pulse may be misread by the TDC, but it only happens as a flip-flop circuit must change state, once in that state no correction pulses will be produced in coming cycles. The timing problem related to FIG. 3 is eliminated, as the flip-flop circuit will be ready to receive clock pulses at all times.

Therefore, according to some embodiments herein, each of the AND gates 35a/35b in the first and second logic gates 321, 322 may be a 3-input AND gate 39a/39b and each of the first and second logic gates 321, 322 further comprises a fourth input 326a/326b. The fourth inputs 326a, 326b of the first and second logic gates 321, 322 are connected to the outputs CU, CD from the first and second flip-flop circuits 311, 312, respectively.

According to some embodiments herein, each of the first and second logic gates 321, 322 may further comprise another AND gate 38a/38b and each of the first and second logic gates 321, 322 further comprises a fourth input 325a/325b. The fourth inputs 325a, 325b of the logic gates 321, 322 are connected to the outputs CU, CD from the first and second flip-flop circuits 311, 312, respectively.

An alternative technique of synchronization, not requiring the use of the PFDs shown in FIGS. 3-5, is to detect in the digital domain, e.g. in the digital processing unit 140, whether a lock in the PLL circuit 100 has been achieved. When the output of each TDC is stable, so that it deviates very little from its averaged value, the PLL has locked. To determine if an output of TDC is stable, it needs to calculate a measure of the deviation, for instance by taking the root mean square (rms) value of the deviation from the average for a number of samples.

Therefore, according to some embodiments herein, the digital processing unit 140 may calculate an averaged value for each TDC by averaging the output values of each TDC over a number of the frequency-divided reference signal cycles and calculate a compensation value by averaging the M averaged values of the M TDCs. Then the digital processing unit 140 may determine if the PLL is locked or not by calculating a measure of the deviation between the output value and the averaged value for each TDC and determining the PLL is locked when all measures of the deviations for the M TDCs are lower than a threshold, or when the root mean square value of all measures of the deviations for the M TDCs is lower than a threshold. The measure of the deviation may be calculated for each TDC by subtracting the averaged value from the output value of each TDC or the measure of the deviation may be calculated as a root mean square value of the deviations between the output values and the averaged value for a number of the frequency-divided reference signal cycles.

If the lock has been reached in the PLL circuit, checking and detecting the deviation pattern for spur elimination. The digital processing unit 140 may be configured to calculate a deviation value for each TDC by subtracting the compensation value from the averaged value of each TDC. If the deviation values are above a certain limit, it means the PFDs are not synchronized, then detecting the largest magnitude of the deviation values of the M PFDs. If the largest magnitude exceeds a threshold and if the deviation value with the largest magnitude is positive, the digital processing unit 140 subtracts an adjustment value from the value of the output signal OutD of the digital processing unit 140 for a number of the frequency-divided reference signal cycles before feeding it to the digital loop filter LF 180. If the deviation value with the largest magnitude is negative, the digital processing unit 140 adds an adjustment value to the value of the output signal OutD of the digital processing unit 140 for a number of the frequency-divided reference signal cycles before feeding it to the digital loop filter LF 180.

Subtracting an adjustment value forces the PLL to compensate by reducing the output frequency (phase) so that the PFD produces a larger output. When the adjustment value to subtract is chosen appropriately, after a number of reference cycles, the PFDs providing the large positive output signals have reached the maximum point of the output signal, i.e. the border for changing state, and after crossing the border, they will enter the other state. Then all PFDs create outputs that are close in magnitude, and the subtraction can be stopped, and the PLL circuit 100 will settle with all PFDs in phase. If instead the largest magnitude of PFDs are negative, an adjustment value is added to the output of the digital processing unit 140 before fed to the loop filter LF 180, with the rest of the procedure being similar. The adjustment value is how much it is needed to alter the output of the digital processing unit 140 to make the PLL circuit 100 change the input signal of the PFDs so much and in the proper direction that the PFDs that are in the wrong state go over the border where they change state. After that all PFDs will be synchronized, i.e. in the same state. The adjustment value will depend on how far the PFDs in the least common state, i.e. that are to be changed, are to the border for changing state. That can be determined from the magnitude of their output, the larger their magnitude, the closer to changing state, and the less adjustment is needed. So the adjustment value may be determined based on the magnitudes of the outputs of those PFDs which states are to be changed.

The advantage of this scheme is that no extra “analog” signals are needed in the PFDs and TDCs. But compared to the scheme of PFDs with synchronization inputs, i.e. Force CD/Force CU, as shown in FIGS. 3-5, it takes some extra time, slowing down settling to the final frequency.

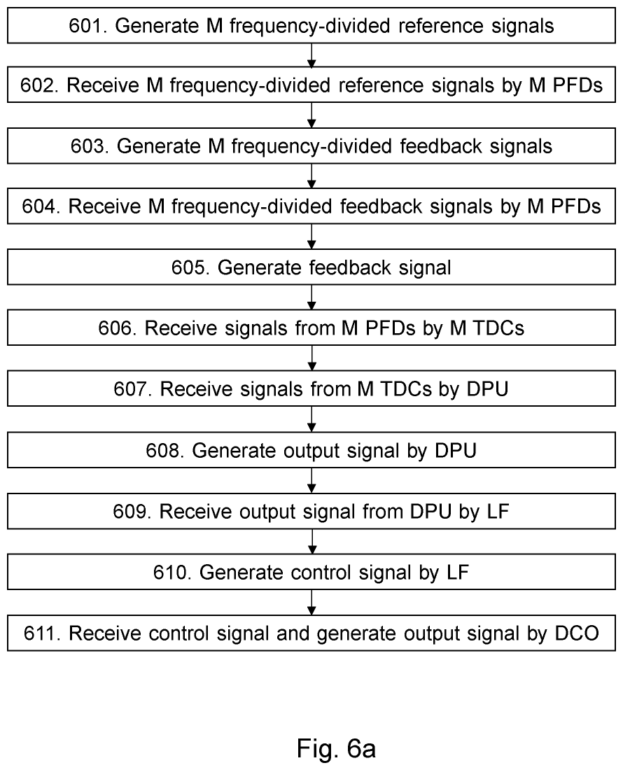

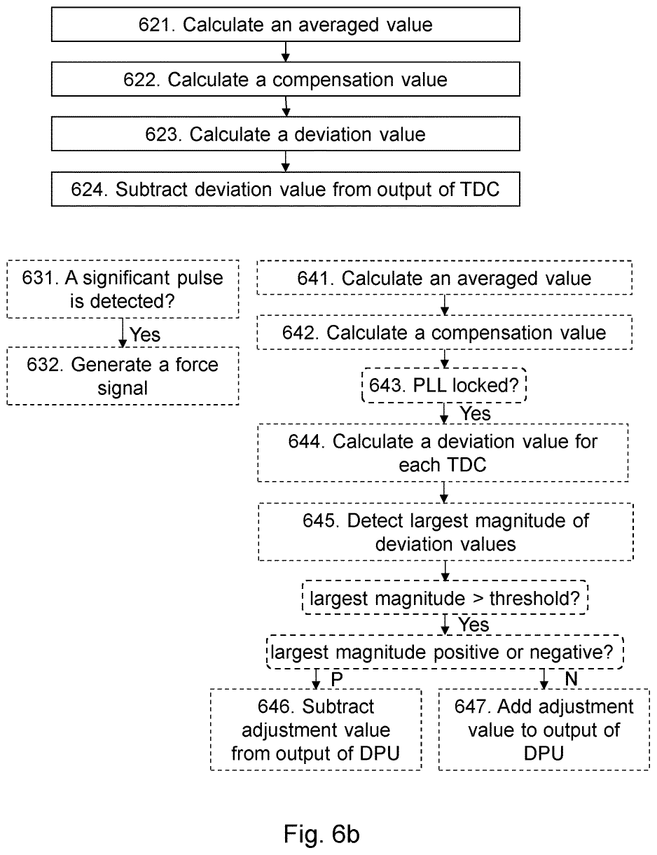

According to one embodiment herein, a method performed in the PLL circuit 100 will be described with reference to FIG. 6a, 6b and FIG. 7. FIG. 6a is a flow chart of the method performed in the PLL circuit 100, FIG. 6b is a flow chart of the method performed in the DPU 140 and FIG. 7 is a block diagram illustrating functional units of the DPU 140 to perform the method. The DPU 140 may comprise a calculating unit CaU 141, a determining unit DU 142, a detecting unit DeU 143, a multiplexing unit MuU 144, a memory unit MeU 145 etc. The method comprises the following actions which may be performed in any suitable order or simultaneously.

### Action 601

Generating M frequency-divided reference signals by a first frequency divider 150 configured to receive a reference signal Ref and frequency divide the reference signal by M. The M frequency-divided reference signals are shifted in time by one period Tr of the reference signal from each other.

### Action 602

Receiving the M frequency-divided reference signals at first inputs RefD of M Phase Frequency Detectors (PFDs) 12-1, 12-2, . . . 12-M respectively.

### Action 603

Generating M frequency-divided feedback signals by a second frequency divider 160 configured to receive a feedback signal FB and frequency divide the feedback signal by M. The M frequency-divided feedback signals are shifted in time by one period Tf of the feedback signal from each other.

### Action 604

Receiving the M frequency-divided feedback signals at second inputs FBD of the M PFDs respectively.

### Action 605

Generating the feedback signal FB to the second frequency divider 160 by a third frequency divider 170 configured to receive an output signal Out from a digitally controlled oscillator (DCO) 110 and frequency divide the output signal from the DCO 110.

### Action 606

Receiving signals from the M PFDs 12-1, 12-2, . . . 12-M by M TDCs 13-1, 13-2, . . . 13-M, respectively.

### Action 607

Receiving signals from the M TDCs 13-1, 13-2, . . . 13-M by a digital processing unit 140.

### Action 608

Generating an output signal OutD per cycle of the reference signal Ref by the digital processing unit 140 based on the received signals from the M TDCs 13-1, 13-2, . . . 13-M.

The digital processing unit 140 may generate an output signal OutD per cycle of the reference signal Ref by, e.g. the multiplexing unit MuU 144 as shown in FIG. 7, being configured to, multiplex the outputs of the M TDCs so that the outputs from the M TDCs are combined to one output signal with a data updating frequency M times the data updating frequency of a single TDC among the M TDCs.

### Action 609

Receiving the output signal OutD from the digital processing unit 140 by a loop filter (180).

### Action 610

Generating a control signal Ctl by the loop filter 180 to the DCO 110.

### Action 611

Receiving the control signal Ctl and generating an output signal Out by the DCO 110. The frequency of the output signal Out generated from the DCO 110 is adjusted by the control signal Ctl.

To mitigate interleaving spurs, the method may further comprise the following actions.

### Action 621

Calculating by e.g. the calculating unit CaU 141 in the digital processing unit 140, an averaged value for each TDC by averaging the output values of each TDC over a number of frequency-divided reference signal cycles.

### Action 622

Calculating by e.g. the calculating unit CaU 141 in the digital processing unit 140, a compensation value by averaging the averaged values of the M TDCs.

### Action 623

Calculating by e.g. the calculating unit CaU 141 in the digital processing unit 140, a deviation value for each TDC by subtracting the compensation value from the averaged value of each TDC.

### Action 624

Subtracting by e.g. the calculating unit CaU 141 in the digital processing unit 140, the M deviation values of TDCs from the respective outputs of the M TDCs.

To synchronize the M PFDs, one PFD 12-1 may be set as a master PFD and the other PFDs as slave PFD, and the method may further comprise the following actions.

### Action 631

Detecting by a TDC 13-1, whether a significant pulse with a polarity of either positive or negative is generated at the output of a master PFD. A pulse being significant means a duration length of the pulse is larger than a threshold.

### Action 632

If a significant pulse is detected, generating a force signal by the TDC 13-1, to other PFDs to enforce the other PFDs to generate output pulses with the same polarity as that of the master PFD 12-1.

Alternatively, to synchronize the M PFDs, the method may further comprise the following actions.

### Action 641

Calculating by e.g. the calculating unit CaU 141 in the digital processing unit 140, an averaged value for each TDC by averaging the output values of each TDC over a number of the frequency-divided reference signal cycles.

### Action 642

Calculating by e.g. the calculating unit CaU 141 in the digital processing unit 140, a compensation value by averaging the M averaged values of the M TDCs.

### Action 643

Determining by e.g. the determining unit DU 142 in the digital processing unit 140, if the PLL is locked or not.

To determine if the PLL is locked or not, the digital processing unit 140 may calculate a measure of the deviation between the output value and the averaged value for each TDC. The PLL is locked when all measures of the deviations for the M TDCs are lower than a threshold, or when the root mean square value of all measures of the deviations for the M TDCs is lower than a threshold.

### Action 644

If the PLL is locked, calculating by e.g. the calculating unit CaU 141 in the digital processing unit 140, a deviation value for each TDC by subtracting the compensation value from the averaged value of each TDC.

### Action 645

Detecting by e.g. the detecting unit DeU 143 in the digital processing unit 140, the largest magnitude of the deviation values of the M PFDs.

### Action 646

If the largest magnitude exceeds a threshold, and if the deviation value with the largest magnitude is positive, subtracting by e.g. the calculating unit CaU 141 in the digital processing unit 140, an adjustment value from the value of the output signal OutD of the digital processing unit 140 for a number of the frequency-divided reference signal cycles.

### Action 647

If the deviation value with the largest magnitude is negative, adding by e.g. the calculating unit CaU 141 in the digital processing unit 140, an adjustment value to the value of the output signal OutD of the digital processing unit 140 for a number of the frequency-divided reference signal cycles.

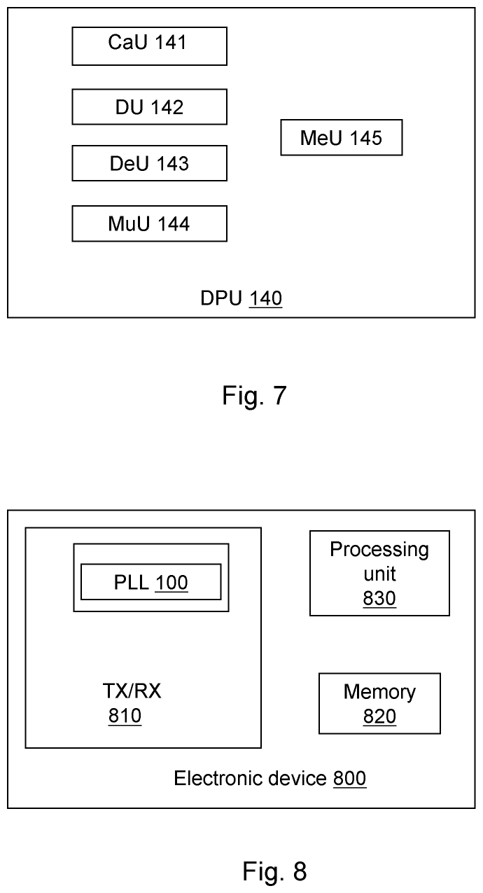

The PLL circuit 100 may be employed in various integrated circuits, electronic circuits, communication devices or apparatus. FIG. 8 shows a block diagram for an electronic device 800 in which the PLL circuit 100 according to embodiments herein may be implemented. The electronic device 800 may comprise a receiver or a transmitter or both i.e. a transceiver TX/RX 810 in which the PLL circuit 100 according to embodiments herein may be implemented. The electronic device 800 may comprise other units, where a memory 820, a processing unit 830 are shown. The electronic device 800 may be any one of a base station, a wireless communication device such as a user equipment or a mobile device for a cellular communication system.

The word “comprise” or “comprising”, when used herein, shall be interpreted as non-limiting, i.e. meaning “consist at least of”.

The embodiments herein are not limited to the above described preferred embodiments. Various alternatives, modifications and equivalents may be used. Therefore, the above embodiments should not be taken as limiting the scope of the invention, which is defined by the appended claims.

1. A Phase Locked Loop, PLL, circuit comprising:
a digitally controlled oscillator, DCO, configured to generate an output signal;
an integer number M of Phase Frequency Detectors, PFDs, each PFD having a first input, a second input and a first output and a second output, one of the M PFDs being a master PFD;
M Time to Digital Converters, TDCs, connected to the outputs of the M PDFs respectively, the TDC connected to the master PFD being configured to:
detect whether a significant pulse with a polarity of either positive or negative is generated at the output of the master PFD, a pulse being significant means a duration length of the pulse is larger than a threshold; and
if a significant pulse is detected, generate a force signal to other PFDs to enforce the other PFDs to generate output pulses with the same polarity as that of the master PFD;
a first frequency divider configured to receive a reference signal and frequency divide the reference signal by M to generate M frequency-divided reference signals shifted in time by one period Tr of the reference signal from each other, wherein the M frequency-divided reference signals are input to the first inputs of the M PFDs respectively;
a second frequency divider configured to receive a feedback signal and frequency divide the feedback signal by M to generate M frequency-divided feedback signals shifted in time by one period Tf of the feedback signal from each other, the M frequency-divided feedback signals being input to the second inputs of the M PFDs respectively;
a third frequency divider configured to receive the output signal from the DCO and frequency divide the output signal from the DCO to generate the feedback signal to the second frequency divider;
a digital processing unit configured to receive signals from the M TDCs and generate an output signal per cycle of the reference signal based on the received signals from the M TDCs; and
a loop filter configured to receive the output signal from the digital processing unit and generate a control signal to the DCO to adjust the frequency of the output signal generated from the DCO.

2. (canceled)

3. The PLL circuit according to claim 1, wherein the force signal comprises a first force signal and a second force signal.

4. The PLL circuit according to claim 1, wherein the threshold is determined based on jitter and mismatches between the M PFDs, between the M TDCs and in the first and second frequency dividers, and the period of the reference signal.

5. The PLL circuit according to claim 1, wherein the digital processing unit is further configured to:
calculate an averaged value for each TDC by averaging the output values of each TDC over a number of the frequency-divided reference signal cycles;
calculate a compensation value by averaging the averaged values of the M TDCs;
calculate a deviation value for each TDC by subtracting the compensation value from the averaged value of each TDC; and
subtract the M deviation values of TDCs from the respective outputs of the M TDCs.

6. The PLL circuit according to claim 1, wherein the digital processing unit is configured to generate an output signal per cycle of the reference signal based on the received signals from the M TDCs by multiplexing the outputs of the M TDCs so that the outputs from the M TDCs are combined to one output signal with a data updating frequency M times the data updating frequency of a single TDC among the M TDCs.

7. The PLL circuit according to claim 5, wherein the digital processing unit is further configured to continuously calculate an averaged value for each TDC over a period of time.

8. The PLL circuit according to claim 3, wherein each PFD comprises:
a first and a second flip-flop circuits each comprising a first, a second and a third inputs, and an output, wherein the first input of the first flip-flop circuit is the first input of the PFD to receive one of the M divided reference signals, the first input of the second flip-flop circuit is the second input of the PFD to receive one of the M divided feedback signals;
a first and a second logic gates, each having a first, a second and a third inputs, and an output, wherein the first and a second logic gates are configured to receive respectively the first and second force signals from the TDC connected to the master PFD and generate a first and second reset signals to the first and a second flip-flop circuits-respectively; and
an AND gate having two inputs and an output, wherein the outputs from the first and second flip-flop circuits are connected to the two inputs of the AND gate respectively, the output of the AND gate is connected to the second inputs of the first and second logic gates.

9. The PLL circuit according to claim 8, wherein each of the first and second logic gates comprises an AND gate, an OR gate and an inverter.

10. The PLL circuit according to claim 9, wherein each of the AND gates in the first and second logic gates is a 3-input AND gate and each of the first and second logic gates further comprise a fourth input, and wherein the fourth inputs of the first and second logic gates are connected to the outputs from the first and second flip-flop circuits respectively.

11. The PLL circuit according to claim 9, wherein each of the first and second logic gates further comprises another AND gate and each of the first and second logic gates further comprise a fourth input, and wherein the fourth inputs of the first and second logic gates are connected to the outputs from the first and second flip-flop circuits respectively.

12. The PLL circuit according to claim 1, wherein the digital processing unit is further configured to:
calculate an averaged value for each TDC by averaging the output values of each TDC over a number of the frequency-divided reference signal cycles;
calculate a compensation value by averaging the M averaged values of the M TDCs;
determine if the PLL is locked or not;
if the PLL is locked, calculate a deviation value for each TDC by subtracting the compensation value from the averaged value of each TDC;
detect the largest magnitude of the deviation values of the M PFDs;
if the largest magnitude exceeds a threshold:
if the deviation value with the largest magnitude is positive, subtract an adjustment value from the value of the output signal of the digital processing unit for a number of the frequency-divided reference signal cycles;
if the deviation value with the largest magnitude is negative, add an adjustment value to the value of the output signal of the digital processing unit for a number of the frequency-divided reference signal cycles.

13. The PLL circuit according to claim 12, wherein the digital processing unit is configured to determine if the PLL is locked or not by being configured to:
calculate a measure of the deviation between the output value and the averaged value for each TDC; and
determine the PLL is locked when all measures of the deviations for the M TDCs are lower than a threshold, or when the root mean square value of all measures of the deviations for the M TDCs is lower than a threshold.

14. The PLL circuit according to claim 13, wherein a measure of the deviation is calculated for each TDC by subtracting the averaged value from the output value of each TDC or as a root mean square value of the deviations between the output values and the averaged value for a number of the frequency-divided reference signal cycles.

15. The PLL circuit according to claim 12, wherein the adjustment value is determined based on the magnitudes of the outputs of those PFDs which states are to be changed.

16. A transceiver comprising two or more Phase Locked Loop, PLL, circuits, each of the two or more PLL circuits comprising:
a digitally controlled oscillator, DCO, configured to generate an output signal;
an integer number M of Phase Frequency Detectors, PFDs, each PFD having a first input, a second input and a first output and a second output, one of the M PFDs being a master PFD;
M Time to Digital Converters, TDCs, connected to the outputs of the M PDFs respectively, the TDC connected to the master PFD being configured to:
detect whether a significant pulse with a polarity of either positive or negative is generated at the output of the master PFD, a pulse being significant means a duration length of the pulse is larger than a threshold; and
if a significant pulse is detected, generate a force signal to other PFDs to enforce the other PFDs to generate output pulses with the same polarity as that of the master PFD;
a first frequency divider configured to receive a reference signal and frequency divide the reference signal by M to generate M frequency-divided reference signals shifted in time by one period Tr of the reference signal from each other, wherein the M frequency-divided reference signals are input to the first inputs of the M PFDs respectively;
a second frequency divider configured to receive a feedback signal and frequency divide the feedback signal by M to generate M frequency-divided feedback signals shifted in time by one period Tf of the feedback signal from each other, the M frequency-divided feedback signals being input to the second inputs of the M PFDs respectively;
a third frequency divider configured to receive the output signal from the DCO and frequency divide the output signal from the DCO to generate the feedback signal to the second frequency divider;
a digital processing unit configured to receive signals from the M TDCs and generate an output signal per cycle of the reference signal based on the received signals from the M TDCs; and
a loop filter configured to receive the output signal from the digital processing unit and generate a control signal to the DCO to adjust the frequency of the output signal generated from the DCO.

17. (canceled)

18. A method performed in a Phase Locked Loop, PLL, circuit for generating an output signal comprising:
generating M frequency-divided reference signals by a first frequency divider configured to receive a reference signal and frequency divide the reference signal by M, wherein the M frequency-divided reference signals are shifted in time by one period Tr of the reference signal from each other;
receiving the M frequency-divided reference signals at first inputs of M Phase Frequency Detectors, PFDs respectively;
generating M frequency-divided feedback signals by a second frequency divider configured to receive a feedback signal and frequency divide the feedback signal by M, wherein the M frequency-divided feedback signals are shifted in time by one period Tf of the feedback signal from each other;
receiving the M frequency-divided feedback signals at second inputs of the M PFDs respectively;
generating the feedback signal to the second frequency divider by a third frequency divider configured to receive an output signal from a digitally controlled oscillator, DCO and frequency divide the output signal from the DCO;
receiving signals from the M PFDs by M TDCs;
detecting by a TDC, whether a significant pulse with a polarity of either positive or negative is generated at the output of a master PFD, a pulse being significant means a duration length of the pulse is larger than a threshold;
if a significant pulse is detected, generating a force signal by the TDC, to other PFDs to enforce the other PFDs to generate output pulses with the same polarity as that of the master PFD;
receiving signals from the M TDCs by a digital processing unit;
generating an output signal per cycle of the reference signal by the digital processing unit based on the received signals from the M TDCs;
receiving the output signal from the digital processing unit by a loop filter;
generating a control signal by the loop filter to the DCO; and
receiving the control signal and generating an output signal by the DCO, wherein the frequency of the output signal generated from the DCO is adjusted by the control signal.

19. The method according to claim 18, further comprising:
calculating by the digital processing unit, an averaged value for each TDC by averaging the output values of each TDC over a number of the frequency-divided reference signal cycles;
calculating by the digital processing unit, a compensation value by averaging the averaged values of the M TDCs;
calculating by the digital processing unit, a deviation value for each TDC by subtracting the compensation value from the averaged value of each TDC; and
subtracting by the digital processing unit, the M deviation values of TDCs from the respective outputs of the M TDCs.

20. The method according to claim 19, wherein generating an output signal per cycle of the reference signal by the digital processing unit based on the received signals from the M TDCs comprises multiplexing the outputs of the M TDCs so that the outputs from the M TDCs are combined to one output signal with a data updating frequency M times the data updating frequency of a single TDC among the M TDCs.

21. (canceled)

22. The method according to claim 18, further comprising:
calculating by the digital processing unit, an averaged value for each TDC by averaging the output values of each TDC over a number of the frequency-divided reference signal cycles;
calculating by the digital processing unit, a compensation value by averaging the M averaged values of the M TDCs;
determining by the digital processing unit, if the PLL is locked or not;
if the PLL is locked, calculating by the digital processing unit, a deviation value for each TDC by subtracting the compensation value from the averaged value of each TDC;
detecting by the digital processing unit, the largest magnitude of the deviation values of the M PFDs;
if the largest magnitude exceeds a threshold, and if the deviation value with the largest magnitude is positive, subtracting by the digital processing unit, an adjustment value from the value of the output signal of the digital processing unit for a number of the frequency-divided reference signal cycles;
if the largest magnitude exceeds a threshold and if the deviation value with the largest magnitude is negative, adding by the digital processing unit, an adjustment value to the value of the output signal of the digital processing unit for a number of the frequency-divided reference signal cycles.

23. The method according to claim 22, wherein determining if the PLL is locked or not comprises:
calculating by the digital processing unit, a measure of the deviation between the output value and the averaged value for each TDC; and
determining by the digital processing unit, the PLL is locked when all measures of the deviations for the M TDCs are lower than a threshold, or when the root mean square value of all measures of the deviations for the M TDCs is lower than a threshold.
